(19) United States
(12) Patent Application Publication
(10) Pub. No.: US 2015/0289382 A1
(43) Pub. Date: Oct. 8, 2015

(54) PRODUCTION METHOD FOR PRINTED WIRING BOARD AND PRINTED WIRING BOARD PRODUCED BY SAID METHOD

(71) Applicant: C. UYEMURA & CO., LTD., Osaka-shi, Osaka (JP)

(72) Inventors: Masaharu Takeuchi, Osaka (JP); Hisamitsu Yamamoto, Osaka (JP); Teruyuki Hotta, Osaka (JP)

(73) Assignee: C. Uyemura & Co., Ltd., Osaka-shi, Osaka (JP)

(21) Appl. No.: 14/649,734

(22) PCT Filed: Oct. 29, 2013
(86) PCT No.: PCT/JP2013/006391

§ 371 Date: Jun. 4, 2015

(30) Foreign Application Priority Data
Dec. 14, 2012 (JP) 2012-273840

(51) Int. Cl. H05K 3/10; H05K 3/42; H05K 1/11

(52) U.S. Cl. CPC H05K 3/107; H05K 1/115; H05K 3/422; H05K 2203/1173

(57) ABSTRACT

This method includes the steps of forming a second resin layer (4) covering a conductor circuit (3) on a first resin layer (2), forming a water-repellent protective layer (8) on the surface (4a) of the second resin layer (4), cutting a via hole (5) and a trench (6) through/in the second resin layer (4) via a through hole (9) of the protective layer (8), applying a catalyst (10) to the second resin layer (4) to allow the catalyst (10) to adhere to the via hole (5) and the trench (6), stripping the protective layer (8) formed on the surface (4a) of the second resin layer 4, and filling the via hole (5) and the trench (6), to each of which the catalyst (10) has adhered, with a plating metal by electroless plating.

### TECHNICAL FIELD

The present invention relates to a method for producing a printed wiring board, and also relates to a printed wiring board. The present invention particularly relates to a method for producing a printed wiring board which can prevent a plating film from adhering onto the surface of the wiring board and which can prevent abnormal plating deposition, and also relates to a printed wiring board produced by such a method.

### BACKGROUND ART

As the electronics industry has developed rapidly, it has become more and more necessary for printed wiring boards to have even higher densities and further enhanced performances, and demands for such printed wiring boards have been growing significantly these days. In particular, the smaller and thinner various state-of-the-art digital devices, including mobile phones, laptop computers, and cameras, have become, the more densely and more finely the wiring patterns of their motherboards need to be arranged. Also, multiple components on a printed wiring board need to be connected together at higher frequencies so often that highly reliable wiring boards that work favorably in processing high-speed signals are now in high demand.

A method for producing a wiring board by semi-additive method or full-additive method is currently adopted as an implementation technique.

In general, a semi-additive method of a build-up process includes, for example, performing electroless copper plating to make an undercoat, forming a circuit pattern using a resist, and then forming a copper circuit by electric copper plating. However, according to such a semi-additive method, current will flow differently depending on, e.g., the density of the copper circuit formed or the shape of the board, thus making the thickness of plating (i.e., the height of the copper circuit) non-uniform. As the feature size of the circuit decreases (i.e., the width of wires themselves and the space between them decrease), misalignment, development errors, and other inconveniences will occur more and more frequently while the resist pattern is being formed. As a result, disconnection, a short-circuit, and other problems may arise easily. Further, the metal copper, which has been formed by the electroless plating process as an electrically conductive undercoat for the electric copper plating, has to be etched away after the electric copper plating process. This etching process may cause, e.g., disconnection of necessary portions of the circuit, or a short-circuit due to insufficient etching more easily, which is also a problem.

On the other hand, a full-additive method includes applying a catalyst onto a base material having blind vias, forming a circuit pattern using a resist after that, and then forming a copper circuit by only an electroless copper plating process. However, according to such a conventional full-additive method, as the feature size of the circuit decreases, misalignment, development errors, and other inconveniences will occur more and more frequently while the resist pattern is being formed, and disconnection, a short-circuit, and other problems may arise easily. According to this method, a part of the catalyst is left under the resist. However, as the feature size of the circuit decreases, the degree of insulation may decrease so significantly between circuits as to cause a short-circuit in some cases.

In order to deal with these problems with conventional implementation technologies, a method has been proposed which includes cutting trenches or via holes in/through the surface of a board using a laser beam, for example, and performing electroless copper plating on the trenches or via holes (see, for example, Patent Document 1).

Also a method has also been proposed which includes filling trenches or via holes with a plating metal using an electroless plating solution containing a sulfur-based organic compound having a cyclic group, for example, without creating defects such as voids or seams. Some documents say that the use of such a method can appropriately produce a printed wiring board with the ability to process high-speed signals or a printed wiring board with high wiring density (see, for example, Patent Document 2).

### CITATION LIST

### Patent Document

PATENT DOCUMENT 1: Japanese Patent application No. 2009-117415

PATENT DOCUMENT 2: Japanese Patent application No. 2010-31361

### SUMMARY OF THE INVENTION

### Technical Problem

However, according to the method disclosed in Patent Document 2, the catalyst is applied to the entire surface of a resin layer made of a resin material with insulation property, and a plating film is also formed over the surface of the board. Thus, unnecessary portions of the plating film have to be removed by, e.g., polishing or etching in a subsequent process step.

As for a board with a large size (for example, 500×600 mm), it is difficult to precisely remove the unnecessary material such as the excessive metal copper by, e.g., polishing or etching, and extra equipment, energy, time, and other resources need to be consumed, resulting in significant decrease in economic efficiency or productivity.

In view of these problems, the present invention has been developed to provide a method for producing a printed wiring board which can prevent a plating film from adhering onto the surface of a resin layer and which can prevent abnormal plating deposition, and also provide a printed wiring board produced by such a method.

### Solution to the Problem

In order to achieve this object, a method for producing a printed wiring board according to the present invention includes at least the steps of: forming a second resin layer over a first resin layer on which a conductor circuit has been formed so that the second resin layer covers the conductor circuit; forming a water-repellent protective layer over the surface of the second resin layer; cutting a through hole through the protective layer, and cutting a via hole and a trench in/through the second resin layer via the through hole; applying a catalyst to the second resin layer to allow the catalyst to adhere to the via hole and the trench; stripping the protective layer that has been formed over the surface of the second resin layer; and filling the via hole and the trench, to each of which the catalyst has adhered, with a plating metal by electroless plating.

Another method for producing a printed wiring board according to the present invention includes at least the steps of: forming, over a first resin layer on which a conductor circuit has been formed, a second resin layer, of which the surface is covered with a water-repellent protective layer, so that the second resin layer covers the conductor circuit; cutting a through hole through the protective layer, and cutting a via hole and a trench in/through the second resin layer via the through hole; applying a catalyst to the second resin layer to allow the catalyst to adhere to the via hole and the trench; stripping the protective layer that has been formed over the surface of the second resin layer; and filling the via hole and the trench, to each of which the catalyst has adhered, with a plating metal by electroless plating.

### Advantages of the Invention

The present invention can reduce a decrease in the productivity of a printed wiring board, and can reduce an increase in cost. The present invention can also prevent the occurrence of abnormal plating deposition due to the adhesion of a catalyst onto the surface of a protective layer.

### BRIEF DESCRIPTION OF THE DRAWINGS

FIG. 1 is a cross-sectional view illustrating a printed wiring board according to a first embodiment of the present invention.

FIGS. 2A-2D are cross-sectional views illustrating a method for producing a printed wiring board according to the first embodiment of the present invention.

FIGS. 3A-2B are cross-sectional views illustrating a method for producing a printed wiring board according to the first embodiment of the present invention.

FIGS. 4A-4C are cross-sectional views illustrating a method for producing a printed wiring board according to a second embodiment of the present invention.

### DESCRIPTION OF EMBODIMENTS

Embodiments of the present invention will now be described in detail with reference to the drawings. The present invention is not limited to the following embodiments.

### First Embodiment

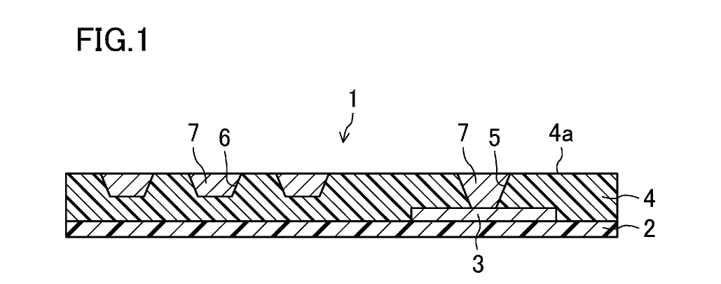

FIG. 1 is a cross-sectional view illustrating a printed wiring board according to a first embodiment of the present invention.

As illustrated in FIG. 1, a printed wiring board 1 according to this embodiment includes a first resin layer 2, a conductor circuit 3 formed on the first resin layer 2, a second resin layer 4 formed on the first resin layer 2 and covering the conductor circuit 3, via holes 5 and trenches 6 which have each been cut through/in the second resin layer 4, and a metal layer 7 filling the via holes 5 and trenches 6.

The first resin layer 2 serves as a base substrate for the printed wiring board 1, and is made of a resin material with electrical insulation property. Examples of materials to make the first resin layer 2 include an epoxy resin, a polyimide resin, a bismaleimide-triazine resin, a polyphenylene ether resin, a liquid crystal polymer, a polyether ether ketone resin, a polyether imide resin, and a polyether sulfone resin.

Alternatively, a plate made of a resin-resin composite material formed by impregnating a fluorine-based resin substrate with a three-dimensional network structure, such as continuous, porous polytetrafluoroethylene resin, with a thermosetting resin, such as an epoxy resin, may also be used.

The conductor circuit 3 is a metallic circuit that defines a wiring pattern for the printed wiring board 1, and is formed by either depositing a metal onto the first resin layer 2 or plating the first resin layer 2.

The conductor circuit 3 may be made of a metal foil, such as copper, aluminum, iron, nickel, chromium, or molybdenum, or an alloy foil thereof (e.g., a copper alloy such as aluminum bronze, phosphor bronze, or yellow bronze, stainless steel, umber, a nickel alloy, or a tin alloy).

The conductor circuit 3 may be implemented as a single layer or stack of any of these metal foils. Among other things, copper or a copper alloy is particularly preferred, because the use of copper or a copper alloy would increase the degree of close contact of the plating and the degree of electrical conductivity, thus eventually reducing the cost.

The second resin layer 4 protects the conductor circuit 3 formed on the surface of the first resin layer 2. The same or similar material as/to that of the first resin layer 2 may be used to make this second resin layer 4.

An epoxy resin is preferably used as the first and second resin layers 2, 4. This is because the epoxy resin is resistant to a plating process. More specifically, the epoxy resin does not allow elution of any harmful substance for a plating solution in an electroless plating process, thus preventing interfacial peeling. This is also because the use of the epoxy resin would increase the degree of close contact with the conductor circuit 3 and the degree of close contact between the first and second resin layers 2 and 4 so much as to prevent peeling, cracking and other inconveniences in a test such as cooling-heating cycle test.

The metal layer 7 is formed by performing a plating process (electroless plating process), specifically, by filling the via holes 5 and trenches 6 with a plating metal. Examples of the metals to make this metal layer 7 include copper and nickel.

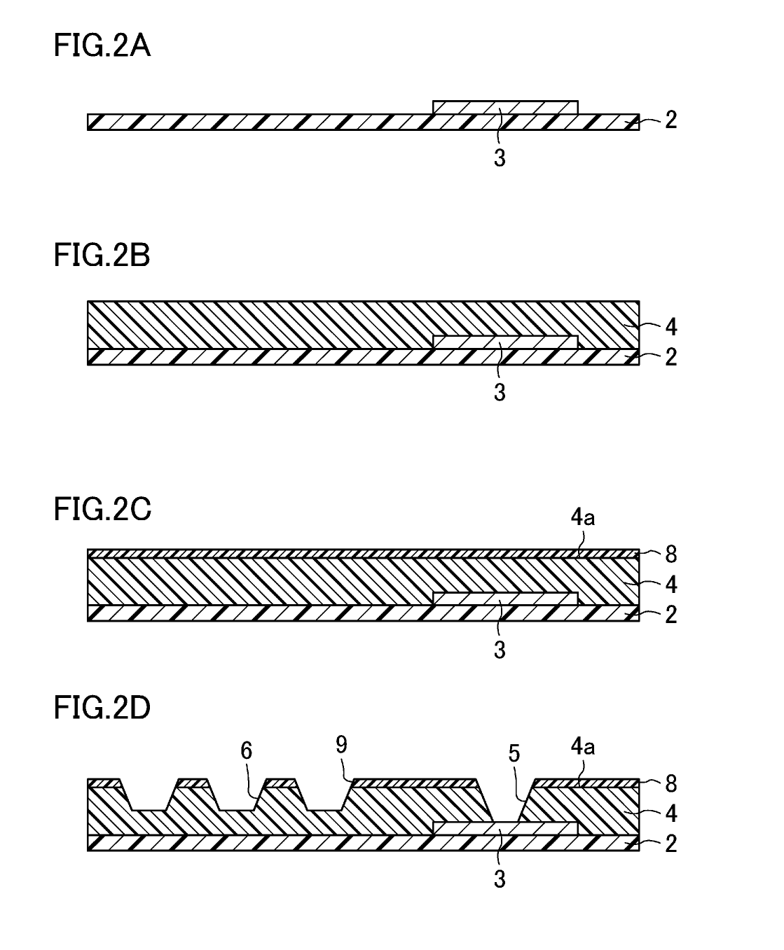

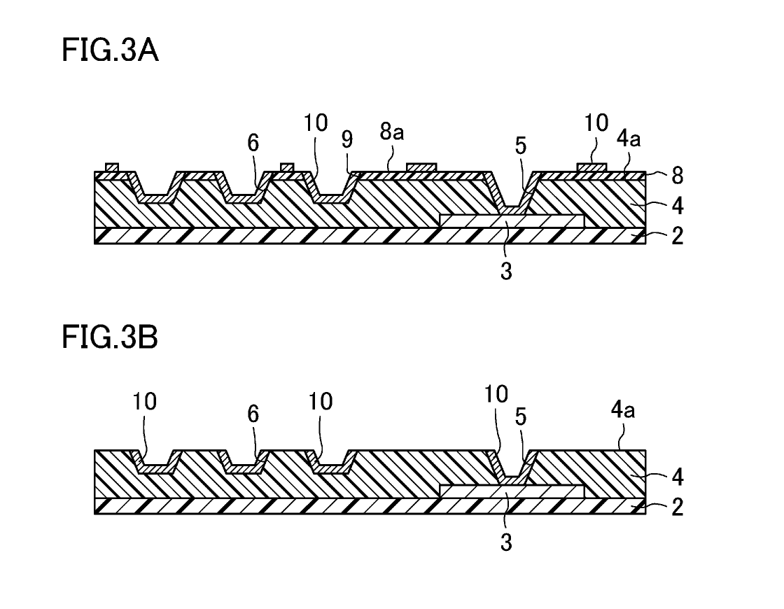

Next, an exemplary method for producing a printed wiring board according to this embodiment will be described. FIGS. 2A-3B are cross-sectional views illustrating a method for producing a printed wiring board according to the first embodiment of the present invention. The production method according to this embodiment includes a conductor circuit forming step, a second resin layer forming step, a protective layer forming step, a via hole and trench forming step, a pre-plating processing step, a catalyst applying step, a protective layer stripping step, and a plating processing step.

<Conductor Circuit Forming Step>

First of all, a copper foil (with a thickness of several um-25 μm), for example, is attached onto the surface of the first resin layer 2 made of, e.g., an epoxy resin to form a copper-clad lamination plate on the surface of the first resin layer 2. Subsequently, this copper-clad laminated plate is patterned by a method such as photolithography, or screen printing to form a conductor circuit 3 on the surface of the first resin layer 2 as illustrated in FIG. 2A.

Alternatively, the copper-clad laminated plate may be formed by plating the first resin layer 2 with copper foil.

<Second Resin Layer Forming Step>

Next, an epoxy resin, for example, is deposited (to a thickness of 20 μm-100 μm) over the first resin layer 2 so as to cover the conductor circuit 3, and then heated and pressed (for example, at a temperature of 100-300° C. and a pressure of 5-60 kg/cm²) to form a second resin layer 4 made of the epoxy resin over the first resin layer 2 so that the second resin layer 4 covers the conductor circuit 3.

Optionally, the second resin layer 4 may be stacked by attaching the second resin layer 4 onto the first resin layer 2 with an adhesive layer (not shown).

<Protective Layer Forming Step>

Next, a polyimide resin, for example, is applied (to a thickness of 0.1 μm-10 μm) onto the second resin layer 4, and then heated to form a protective layer 8 of the polyimide resin over the second resin layer 4, as illustrated in FIG. 2C.

Optionally, when the protective layer 8 is stacked on the second resin layer 4, an adhesive layer (not shown) may be applied onto the second resin layer 4, and then the protective layer 8 may be stacked over the second resin layer 4 with the adhesive layer interposed between them. In this case, a heat-resistant adhesive sheet or any other appropriate member made of, e.g., a polyamide resin, a polyester resin, a polyolefin resin, or a polyurethane resin may be used as the adhesive layer, and may be fused under heat to form the adhesive layer. The adhesive layer may be fused and bonded under any condition without particular limitation, and the condition may be modified as appropriate according to the resin to make the adhesive sheet, etc. For example, the adhesive sheet may be fused under heat at a temperature of about 100-190° C. for 30 seconds-2 minutes to form the adhesive layer.

This protective layer 8 is provided in order to allow a catalyst to adhere to only the via holes 5 and trenches 6 in the second resin layer 4 in the catalyst applying step to be described later, and to prevent the catalyst from adhering to the surface 4a of the second resin layer 4 (see FIGS. 1 and 2C).

This protective layer 8 is made of a resin which has electrically insulation property and water-repellency and which is soluble in a stripping solution for use in the protective layer stripping step to be described later. Examples of the resins to make the protective layer 8 include an alkali-soluble resin such as a polyimide resin, a silicon resin, a phenol resin, a xylene resin, an unsaturated polyester resin, a diallylphthalate resin, an acrylic resin, and a polycarbonate resin, or an alcohol soluble resin such as an acrylic resin, a phenol resin, an ABS resin, and a polyisobutylene resin.

The protective layer 8 preferably has a thickness of 0.1 μm-10 μm. That is because if the thickness of the protective layer 8 were less than 0.1 μm, the function of allowing the catalyst to adhere to only the via holes 5 and trenches 6 without allowing the catalyst to adhere to the surface 4a of the second resin layer 4 might decline in the catalyst applying step to be described later. Nevertheless, if the thickness of the protective layer 8 were more than 10 μm, the depth of the trench 6 cut in the protective layer 8 would increase too much to form trenches 6 easily in the printed wiring board 1 when the trenches 6 have a narrower width.

<Via Hole and Trench Forming Step>

Next, as illustrated in FIG. 2D, through holes 9 are cut through the protective layer 8 on the second resin layer 4, and via holes 5 and trenches 6 are cut via the through holes 9 through/in the second resin layer 4 on which the protective layer 8 is stacked.

Any method may be used to cut the via holes 5, trenches 6, and through holes 9 without particular limitation, and examples of the methods include etching, and laser processing. Of these methods, the laser processing is preferably used to form the via holes 5 and other holes in order to rapidly form fine-line via holes 5 and other holes, avoid inconveniences such as misalignment and development errors due to defective exposure and development during etching, and to form a wiring pattern with high reliability, no matter how much the size and thickness of the wiring board are reduced or its density is increased.

When the via holes 5 and other holes are formed by such laser processing, a general laser diode, such as a CO₂ laser diode, a YAG laser diode, or an excimer laser diode, may be used. Alternatively, a gas laser diode such as an argon laser diode or a helium-neon laser diode, a solid-state laser diode such as a sapphire laser diode, a dye laser diode, a semiconductor laser diode, or a free electron laser diode may also be used, for example. Among these laser diodes, a YAG laser diode or an excimer laser diode is particularly preferred in order to form fine-line via holes 5 and other holes.

The aspect ratio, diameter, depth, and other parameters of the via holes 6 may be changed as appropriate according to, e.g., the type of the printed wiring board 1.

<Pre-Plating Processing Step>

Subsequently, the board in which the via holes 5 and trenches 6 have been formed is subjected to predetermined pre-plating processing. More specifically, the board is immersed in, for example, a purifying solution (such as an acid solution or a neutral solution) at a temperature of 65° C. for 5 minutes to remove dust from the board surface, via holes 5, and trenches 6. This purifying process cleans the inside of the via holes 5 and trenches 6 to increase the degree of close contact of the plating film to be formed in a subsequent process step.

Optionally, the surface of the conductor circuit 3 exposed at the bottom of the via holes 5 may be subjected to an activation process. This activation process is performed by immersing the board in an acid solution for 5-10 seconds using, e.g., an acid solution containing 10% of sulfuric acid or hydrochloric acid. By immersing the board in the acid solution in this manner, an alkaline substance left on the surface of the conductor circuit 3 that is an activated region can be neutralized and a thin oxide film can be dissolved.

<Catalyst Applying Step>

Subsequently, as illustrated in FIG. 3A, a catalyst 10 is applied to the second resin layer 4 and allowed to adhere to the via holes 5 and trenches 6 that have been cut through/in the second resin layer 4.

At this time, the protective layer 8 with water-repellent property has been formed on the surface 4a of the second resin layer 4, as described above. Thus, in this step, the protective layer 8 repels the catalyst solution on the surface 4a of the second resin layer 4 except the via holes 5 and trenches 6. This enables the catalyst 10 to adhere to only the via holes 5 and trenches 6 which have been formed in the second resin layer 4, and prevents the catalyst 10 from adhering to the surface 4a of the second resin layer 4, as illustrated in FIG. 3A.

Therefore, this will also prevent a plating film from adhering to the surface 4a of the second resin layer 4 in the plating process step to be described later, and thus prevent any plated metal layer (plating film) from being formed on the surface 4a of the second resin layer 4. Consequently, there is no need to remove any unnecessary plating film by polishing, etching, or any other process. As a result, extra equipment, time, and other resources, to remove such an unnecessary plating film are no longer needed, thus reducing a decrease in productivity and an increase in cost for the printed wiring board 1.

This also prevents the occurrence of various inconveniences such as disconnection and/or a short-circuit of the conductor circuit 3 due to the presence of such an unnecessary plating film.

This process step may be performed using a catalyst solution containing, e.g., divalent palladium ions (Pd²⁺). For example, a mixed solution of palladium chloride (PdCl₂.2H₂O) containing 100-300 mg/l of Pd, stannous chloride (SnCl₂.2H₂O) containing 10-20 g/l of Sn, and 150-250 ml/l of hydrochloric acid (HCl) may be used as the catalyst solution in this process step.

The catalyst 10 may be applied as follows. First, the board illustrated in FIG. 2D is immersed in the catalyst solution at, e.g., a temperature of 30-40° C. for, e.g., 1-3 minutes to allow Pd-Sn colloid to be adsorbed onto the surface of the board. Subsequently, the board is immersed in an accelerator containing 50-100 ml/l of sulfuric acid or hydrochloric acid at a normal temperature to activate the catalyst. This activation process removes tin of the complex compound to form palladium adsorbed particles, and such particles, finally serving as a palladium catalyst, promotes deposition of metal plating by the electroless plating process.

A catalyst solution containing copper ions (Cu²⁺) may be used and applied as the catalyst 10. A catalyst solution of acid colloid type or alkali ion type containing no tin may be used. A sodium hydroxide or ammonia solution may be used as the accelerator mentioned above.

A pretreatment may be performed using a conditioner solution or a pre-dip solution to increase the degree of close contact between the metal layer 7 and the second resin layer 4 in the via holes 5 and trenches 6. The method may include applying a catalyst by, e.g., ejecting the catalyst solution toward the board by a spraying method and bringing the catalyst into contact with the board.

<Protective Layer Peeling Step>

Subsequently, the protective layer 8 formed on the surface 4a of the second resin layer 4 is stripped with a stripping solution, as illustrated in FIG. 3B. More specifically, the board illustrated in FIG. 3A, on which the catalyst 10 is applied, is immersed in the stripping solution to dissolve the protective layer 8 in the stripping solution, thus stripping the protective layer 8 that has been formed on the surface 4a of the second resin layer 4.

At this time, even if the catalyst 10 has adhered to the surface 8a of the protective layer 8 as illustrated in FIG. 3A, the catalyst 10 adhered to the surface of the protective layer 8 is also removed simultaneously when the protective layer 8 is stripped, as illustrated in FIG. B. As a result, the catalyst 10 still adheres to only the via holes 5 and trenches 6.

Specifically, although the water-repellent protective layer 8 is used as described above in this embodiment, the catalyst 10 may adhere onto the surface 8a of the protective layer 8 in the catalyst applying step as illustrated in FIG. 3A. If the plating process to be described later were performed with the catalyst 10 adhered onto the surface 8a of the protective layer 8, abnormal plating deposition would occur due to the adhesion of the catalyst 10 onto the surface 8a of the protective layer 8.

Thus, according to this embodiment, the protective layer 8 is stripped before the plating process, and the catalyst 10 adhered onto the surface of the protective layer 8 is removed simultaneously when the protective layer 8 is stripped, thus preventing abnormal plating deposition due to the adhesion of the catalyst 10 onto the surface 8a of the protective layer 8.

The stripping solution to use may be changed as appropriate according to the type of the resin that makes the protective layer 8 to be stripped. For example, if the protective layer 8 is made of a resin soluble in an alkaline aqueous solution, such as the polyimide resin or the silicon resin described above, an alkali metal hydroxide aqueous solution such as a sodium hydroxide aqueous solution or a potassium hydroxide aqueous solution may be used as the stripping solution. If the protective layer 8 is made of a resin soluble in an alcohol solution such as the acrylic resin or the phenol resin described above, an alcohol solution such as isopropyl alcohol may be used as the stripping solution.

In this step, it is preferable to use a stripping solution with a low concentration. More specifically, the stripping solution preferably has a concentration of 0.5 mol/l or less. The reason is as follows. Specifically, if the concentration of the stripping solution were more than 0.5 mol/l, the stripping solution could remove the catalyst 10 adhered to the via holes 5 and trenches 6 too much to deposit a plating film in the plating process to be described later, which is an inconvenience to avoid. Thus, setting the concentration of the stripping solution to be 0.5 mol/l or less makes it possible to prevent the catalyst 10 adhered to the via holes 5 and trenches 6 from being removed too much to deposit a plating film in the plating process described later.

The technique of stripping the protective layer 8 by immersing the board (i.e., the protective layer 8) in the stripping solution is adopted in this process step for the same reasons, i.e., to prevent the catalyst 10 adhered to the via holes 5 and trenches 6 from being removed too much to deposit a plating film in the plating process to be described later.

The duration of immersion of the protective layer 8 in the stripping solution may be changed as appropriate according to the type of the resin that makes the protective layer 8, the concentration of the stripping solution, and other factors. For example, if the protective layer 8 made of a polyimide resin is going to be stripped using a sodium hydroxide aqueous solution with a concentration of 0.4 mol/l, the duration of immersion may be set to be 30 seconds to 120 seconds. In this way, the duration of immersion is set according to the concentration of the stripping solution to use, thus ensuring that the protective layer 8 is stripped without removing unintentionally the catalyst 10 adhered to the via holes 5 and trenches 6.

<Plating Processing Step>

Subsequently, the metal layer 7 to be patterned into a circuit of the printed wiring board 1 is formed by plating (electroless plating) the board to which the catalyst 10 has been applied as illustrated in FIG. 3B, i.e., by filling the via holes 5 and trenches 6, to each of which the catalyst 10 has adhered, with a plating metal.

Any electroless plating solution may be used in this process step without particular limitation. For example, an electroless plating solution may be used which contains a water-soluble metal salt such as a water-soluble cupric (alloy) salt or a water-soluble nickel (alloy) salt as a main component, and one or more reducing agents such as formaldehyde, paraformaldehyde, glyoxylic acid or a salt thereof, hypophosphoric acid or a salt thereof, and dimethylaminoborane, a complexing agent such as ethylenediaminetetraacetic acid tetrasodium or potassium sodium tartrate, and at least one sulfur-based organic compound as a leveler.

The use of such an electroless plating solution containing a sulfur-based organic compound as a leveler allows for filling the via holes 5 and trenches 6 with a plating metal just as intended with the occurrence of defects such as voids or seams suppressed for a long time.

The electroless plating solution may contain any metal without particular limitation. For example, the electroless plating solution may contain copper or nickel as metal ions. Among other things, an electroless copper plating solution containing copper ions is particularly preferred in order to increase the degree of close contact with the second resin layer 4 in the via holes 5 and trenches 6 and to improve the electrical characteristics of a plating deposited.

Optionally, the electroless plating solution may contain a surfactant, a plating deposition accelerator, or any other appropriate agent, as needed. This solution may also contain a known stabilizer such as 2,2-bipyridyl or 1,10-phenanthroline, and/or an additive such as an additive to improve physical properties of the plating film.

The duration of the plating process is not particularly limited, either, and may be changed as appropriate according to the sizes of the via hole 5 and trenches 6, or any other factor. For example, the board to which the catalyst has been applied may be immersed in the electroless plating solution for 30-600 minutes.

The plating process may be performed at any temperature without particular limitation as long as metal ions such as copper ions are reduced at that temperature. In order to trigger the reduction reaction efficiently, the temperature of the plating solution is preferably set to be 20-90° C., and more preferably set to be 50-70° C.

The electroless plating solution may be used at any pH without particular lamination, but it is preferable to set the pH to be 10-14. In this way, setting pH of the electroless plating solution within such a high alkaline condition range efficiently advances a reduction reaction of the metal ions such as copper ions, and increases the deposition rate of the metal plating film. The electroless plating solution may contain a pH regulator such as sodium hydroxide, potassium hydroxide, or tetramethylammonium hydroxide to maintain its pH within the range of 10 to 14. Such a pH regulator is diluted with water and added to the plating solution, as appropriate.

In performing the electroless plating process, it is preferable to stir the plating solution well enough to supply ions sufficiently to the via holes 5 and trenches 6. For example, pneumatic agitation, or pump circulation may be adopted as a method for stirring the plating solution.

By performing such a plating process, the metal layer 7 formed in the via holes 5 is connected to the conductor circuit 3 through the via holes 5, and the metal layer 7 formed in the trenches 6 defines the wiring pattern according to this embodiment.

In this way, the printed wiring board 1 illustrated in FIG. 1 is produced.

The following advantages are achieved by the embodiment described above.

(1) According to this embodiment, the method includes the steps of forming a water-repellent protective layer 8 on the surface 4a of a second resin layer 4, cutting a through hole 9 through the protective layer 8 formed on the second resin layer 4, and cutting a via hole 5 and a trench 6 through/in the second resin layer 4 via the through hole 9. Also, according to this embodiment, the method further includes the steps of applying a catalyst 10 onto the second resin layer 4 to allow the catalyst 10 to adhere to the via hole 5 and the trench 6 which have been cut though/in the second resin layer 4, and filling the via hole 5 and the trench 6, to each of which the catalyst 10 has adhered, with a plating metal by electroless plating. This causes the catalyst 10 to adhere to only the via hole 5 and the trench 6 which have been cut through/in the second resin layer 4 without allowing the catalyst 10 to adhering to the surface 4a of the second resin layer 4. Therefore, no plating film is allowed to be deposited onto the surface 4a of the second resin layer 4 during the plating process, and therefore, there is no need to remove an unnecessary plating film. As a result, no equipment, time, and other resources, are needed anymore to remove such an unnecessary plating film, thus preventing a decrease in productivity and an increase in cost of the printed wiring board 1. It also becomes possible to prevent the occurrence of various inconveniences such as disconnection or a short-circuit of the conductor circuit 3 due to the presence of such an unnecessary plating film.

(2) According to this embodiment, the protective layer 8 formed on the surface 4a of the second resin layer 4 is supposed to be stripped after the application of the catalyst and before the plating process. This allows removal of the catalyst 10 adhered onto the surface of the protective layer 8 simultaneously when the protective layer 8 is stripped even if the catalyst 10 has adhered onto the surface 8a of the protective layer 8 before the plating process. As a result, it becomes possible to prevent the occurrence of abnormal plating deposition due to the adhesion of the catalyst 10 onto the surface 8a of the protective layer 8.

(3) According to this embodiment, the protective layer 8 is supposed to be stripped using a stripping solution. Thus, the catalyst 10 adhered on the surface of the protective layer 8 can be removed by such an easy method.

(4) According to this embodiment, an alkali metal aqueous solution or an alcohol solution is supposed to be used as a stripping solution. Accordingly, the catalyst 10 adhered on the surface of the protective layer 8 can be removed with an inexpensive and universal solution.

(5) According to this embodiment, the stripping solution with a concentration of 0.5 mol/l or less is supposed to be used. This prevents the catalyst 10 adhered to the via holes 5 and trenches 6 from being removed too much to deposit a plating film in the plating process.

(6) According to this embodiment, the protective layer 8 is supposed to be stripped by being immersed in the stripping solution. This prevents the catalyst 10 adhered to the via holes 5 and trenches 6 from being removed too much to deposit a plating film in the plating process.

### Second Embodiment

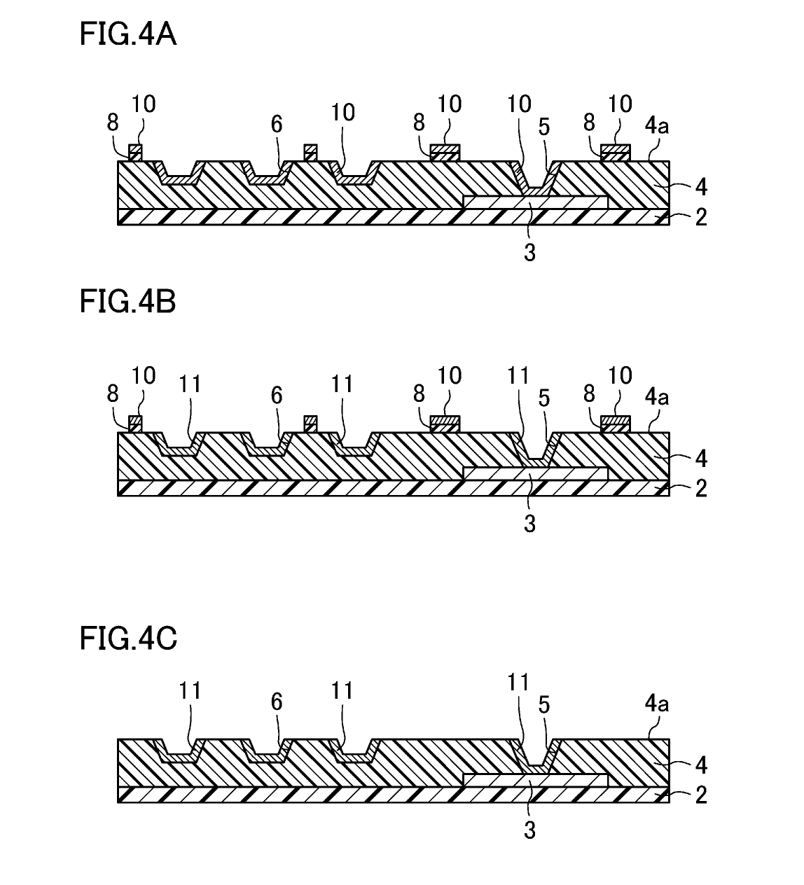

A second embodiment of the present invention will be described next. FIGS. 4A-4C are cross-sectional views showing a method for producing a printed wiring board according to the second embodiment of the present invention. The same or similar elements as those of the first embodiment are identified by the same reference characters and description thereof will be omitted.

According to the first embodiment described above, in order to prevent the occurrence of abnormal plating deposition due to the adhesion of the catalyst 10 onto the surface 8a of the protective layer 8, the protective layer 8 is stripped using a stripping solution as illustrated in FIG. 3B, thereby removing the catalyst 10 adhered onto the surface of the protective layer 8.

However, in this protective layer stripping step, the protective layer 8 may not be stripped completely but may be partially left, as illustrated in FIG. 4A.

In such a case, abnormal plating deposition occurs due to the adhesion of the catalyst 10 onto the surface of the residual protective layer 8.

In order to avoid such an inconvenience, according to this embodiment, an undercoat plating process step and a second protective layer stripping step (i.e., the step of stripping the residual protective layer) are performed after the protective layer stripping step described above.

<Undercoat Plating Process Step>

After the protective layer stripping step described above, an electroless plating process is performed in the same or similar manner as/to the plating process described above with part of the protective layer 8 still left on the surface of the second resin layer 4, as illustrated in FIG. 4A, thereby forming a plating film 11 on the respective surfaces of the via holes 5 and trenches 6, to each of which the catalyst 10 has adhered, as illustrated in FIG. 4B.

The same or similar electroless plating solution as/to that used in the plating process step described above may be used in this process step.

Although the duration of the plating process is not particularly limited but may be changed as appropriate according to the sizes of the via holes 5 and trenches 6 or any other factor, the duration may be set to be shorter than that in the plating process step described above. For example, the board on which the catalyst has been applied may be immersed in the electroless plating solution for 5-10 minutes.

<Second Protective Layer Stripping Step>

Subsequently, the protective layer 8 left on the surface 4a of the second resin layer 4 is stripped using a stripping solution, as illustrated in FIG. 4C. More specifically, the stripping solution is sprayed on, and brought into contact with, the residual protective layer 8, thereby stripping the protective layer 8 left on the surface 4a of the second resin layer 4.

According to such a method, even if the protective layer 8 has not been stripped completely but partially left in the protective layer stripping step described above, this process step allows for removal of such a residual part of the protective layer 8 from the surface 4a of the second resin layer 4. This ensures that no abnormal plating deposition will occur due to the adhesion of the catalyst 10 onto the surface 8a of the protective layer 8.

As in the protective layer stripping step described above, an alkali metal hydroxide aqueous solution or an alcohol solution may be used in this step as a stripping solution. In this step, it is preferable to use a stripping solution with a higher concentration than the one used in the protective layer stripping step described above in order to ensure that the protective layer 8 left on the surface 4a of the second resin layer 4 is removed as intended.

More specifically, the stripping solution preferably has a concentration of 0.4 mol/l to 1.5 mol/l. The reason is as follows. Specifically, if the concentration of the stripping solution were less than 0.4 mol/l, sometimes it could be difficult to ensure that the protective layer 8 left on the surface 4a of the second resin layer 4 is removed as intended. However, if the concentration of the stripping solution were more than 1.5 mol/l, the stripping solution might sometimes remove unintentionally the plating film 11 formed in the via holes 5 and the trenches 6. That is, setting the concentration of the stripping solution to be equal to or higher than 0.4 mol/l and equal to or lower than 1.5 mol/l ensures that the protective layer 8 left on the surface 4a of the second resin layer 4 is removed as intended without removing the plating film 11 from the via holes 5 and trenches 6.

For example, if a stripping solution with a concentration of 0.3 mol/l has been used in the protective layer stripping step described above, a stripping solution with a concentration of 0.4 mol/l may be used in this process step (namely, the second protective layer stripping step).

In this embodiment, the plating film 11 has already been formed on the respective surfaces of the via holes 5 and trenches 6 in the undercoat plating process step described above. That is why the no-plating-deposition problem can be avoided even if a stripping solution with a higher concentration than the one used in the protective layer stripping step described above is used in this process step.

In order to remove the protective layer 8 just as intended, it is preferable to spray the stripping solution so as to bring the stripping solution into contact with the entire protective layer 8. For example, the stripping solution may be brought into contact with the entire protective layer 8 either with the spraying nozzle ejecting the stripping solution swung or with the protective layer 8 moved (transferred) while the spraying nozzle ejecting the stripping solution is fixed.

Likewise, in order to ensure that the protective layer 8 left on the surface 4a of the second resin layer 4 is removed as intended, the protective layer 8 may be stripped by ejecting the stripping solution by spraying method toward the board (i.e., the protective layer 8) illustrated in FIG. 4B and bringing the stripping solution into contact with the board in this step, instead of immersing the protective layer 8 in the stripping solution.

The duration of spraying the stripping solution onto the protective layer 8, and its spraying flow rate may be changed as appropriate according to the resin that makes the protective layer 8, the concentration of the stripping solution, or any other factor. For example, if the protective layer 8 made of a polyimide resin is stripped using a sodium hydroxide aqueous solution with a concentration of 1.0 mol/l, the spraying flow rate may be set to be 190 L/min and the duration of spraying may be set to be 180 seconds to 600 seconds. In this way, the duration of spraying the stripping solution and its spraying flow rate may be set according to the type of the resin that makes the protective layer 8 and the concentration of the stripping solution to use, thus ensuring that the protective layer 8 left on the surface 4a of the second resin layer 4 should be removed more perfectly.

Subsequently, the board from which the protective layer 8 has been completely removed as illustrated in FIG. 4C is subjected to the plating process as described for the first embodiment to form a metal layer 7 over the plating film 11. As a result, the printed wiring board 1 illustrated in FIG. 1 is completed.

The following advantages are also achieved according to this embodiment in addition to the advantages (1)-(6) described above.

(7) The method of this embodiment includes the steps of forming a plating film 11 over the surfaces of the via holes 5 and trenches 6, to which the catalyst 10 has adhered, by electroless plating after the protective layer stripping step, and stripping the protective layer 8 left on the surface 4a of the second resin layer 4. This allows for avoiding the no-plating-deposition problem and removing the protective layer 8 left on the surface 4a of the second resin layer 4 after the protective layer stripping step. As a result, it is possible to ensure that no abnormal plating deposition should occur due to the adhesion of the catalyst 10 on the surface 8a of the protective layer 8.

(8) According to this embodiment, the protective layer 8 left on the surface 4a of the second resin layer 4 is stripped using the stripping solution in the second protective layer stripping step. Thus, the catalyst 10 adhered onto the surface of the protective layer 8 left on the surface 4a of the second resin layer 4 can be removed by such an easy method.

(9) According to this embodiment, an alkali metal aqueous solution or an alcohol solution is used as the stripping solution in the second protective layer stripping step.

Accordingly, the catalyst 10 adhered onto the surface of the protective layer 8 left on the surface 4a of the second resin layer 4 can be removed with an inexpensive and universal solution.

(10) According to this embodiment, a stripping solution with a concentration of 0.4 mol/l to 1.5 mol/l is used in the second protective layer stripping step. Thus, this method allows for removal of the protective layer 8 left on the surface 4a of the second resin layer 4 without removing unintentionally the plating film 11 formed in the via holes 5 and trenches 6.

(11) According to this embodiment, the stripping solution is ejected by the spraying method toward, and brought into contact with, the protective layer 8 in the second protective layer stripping step, thereby stripping the protective layer 8. Thus, this method ensures that the protective layer 8 left on the surface 4a of the second resin layer 4 is removed as intended.

The embodiments described above may be modified as follows.

According to the embodiments described above, the protective layer 8 is supposed to be formed over the second resin layer 4 after the second resin layer 4 has been formed over the first resin layer 2 on which the conductor circuit 3 has been formed. Alternatively, a second resin layer 4, of which the surface is coated with the protective layer 8, may be stacked on the first resin layer 2 on which the conductor circuit 3 has been formed. That is, the second resin layer 4 with the protective layer 8 may be stacked on the first resin layer 2, on which the conductor circuit 3 has been formed, so as to cover the conductor circuit 3.

### EXAMPLES

The present invention will now be described by way of illustrative examples. The present invention is not limited to these examples but is readily modifiable and changeable without departing from the scope and sprit of the present invention.

### Example 1

A second resin layer made of an epoxy resin (product name: ABF-GX13 manufactured by Ajinomoto Fine-Techno Co., Inc.) and having a thickness of 40 μm was prepared, and a polyimide resin was applied to a thickness of 2 μm onto the second resin layer. Thereafter, this polyimide resin was heated to form a protective layer made of the polyimide resin over the second resin layer.

Subsequently, a through hole was cut through the protective layer formed on the second resin layer using a laser beam machine (product name: LC-L manufactured by Hitachi Via Mechanics, Ltd.), and trenches having a width of 20 μm and a depth of 20 μm were cut via the through hole.

Subsequently, the second resin layer with the protective layer was immersed in a catalyst solution containing divalent palladium ions (Pd²) (product name: Thru-Cup AT-105 manufactured by C. Uyemura & Co., Ltd.) at a temperature of 30° C. for 8 minutes to adsorb Pd—Sn colloids. Thereafter, the catalyst was activated by immersing the resin layer in sulfuric acid (accelerator) with a concentration of 100 ml/l at a normal temperature, thereby applying the catalyst to the second resin layer and allowing the catalyst to adhere to the trenched cut in the second resin layer.

Subsequently, the second resin layer to which the catalyst had been applied was immersed in a sodium hydroxide aqueous solution with a concentration of 0.38 mol/l used as a stripping solution at a temperature of 25° C. for 1 minute to strip the protective layer (this is the first protective layer stripping step).

Subsequently, the second resin layer from which the protective layer had been stripped was immersed in an electroless plating solution having the following composition for 10 minutes to form a plating film (copper plating film) having a thickness of 0.3 μm on the surface of the trenches to which the catalyst had adhered.

<Composition of Electroless Copper Plating Solution>

Copper Sulfate: 0.04 mol/l

EDTA: 0.1 mol/l

Sodium Hydroxide: 4 g/l

Formaldehyde: 4 g/l

2,2′-Bipyridyl: 2 mg/l

Polyethylene Glycol (Molecular Weight 1000): 1000 mg/l

2,2′-Dipyridyl Disulphide: 5 mg/l

Subsequently, a sodium hydroxide aqueous solution with a concentration of 1.0 mol/l was used as the stripping solution, and ejected by a spraying method toward the second resin layer on which the plating film had been formed using a spraying device (produced by C. Uyemura & Co., Ltd.) to bring the solution into contact with the layer. In this manner, the protective layer left on the second resin layer was removed (this is the second protective layer stripping step).

The duration of spraying the stripping solution was set to be 300 seconds, and its spraying flow rate was set to be 190 L/min.

Subsequently, the second resin layer from which the residual protective layer had been removed was immersed for 120 minutes in an electroless plating solution having the following composition, and the trenches coated with the plating film as an undercoat were filled with a plating metal (copper) to form a metal layer having a thickness of 20 μm.

<Composition of Electroless Copper Plating Solution>

Copper Sulfate: 0.04 mol/l

EDTA: 0.1 mol/l

Sodium Hydroxide: 4 g/l

Formaldehyde: 4 g/l

2,2′-Bipyridyl: 2 mg/l

Polyethylene Glycol (Molecular Weight 1000): 1000 mg/l

2,2′-Dipyridyl Disulphide :5 mg/l

### Example 2

The second resin layer of which the trenches were filled with a metal layer was formed in the same manner as Example 1 described above except that the concentration of the sodium hydroxide aqueous solution used in the first stripping step was changed into 0.5 mol/l, and the concentration of the sodium hydroxide aqueous solution used in the second stripping step was changed into 0.7 mol/l.

### Example 3

The second resin layer of which the trenches were filled with a metal layer was formed in the same manner as Example 1 described above except that the concentration of the sodium hydroxide aqueous solution used in the first stripping step was changed into 0.3 mol/l, and the concentration of the sodium hydroxide aqueous solution used in the second stripping step was changed into 0.4 mol/l.

### Example 4

The second resin layer of which the trenches were filled with a metal layer was formed in the same manner as Example 1 described above except that the concentration of the sodium hydroxide aqueous solution used in the first stripping step was changed into 0.4 mol/l, and the concentration of the sodium hydroxide aqueous solution used in the second stripping step was changed into 1.5 mol/l.

(Evaluation of Plating Deposition and Fillability)

Subsequently, the surface of the second resin layer and a cross section of the trenches which had been formed in each of Examples 1-4 were observed through an electron microscope (product name: DM13000M manufactured by Leica Camera) to determine whether or not the plating had been deposited on the surface, and how well the trenches were filled with the metal layer (examine its fillability). The ability to fill the trenches with the metal layer was determined to be good if no void or seams were observed in the cross section.

The cross-section was observed by, first of all, putting the second resin layer that had been plated in a case of polyprene (with a diameter of 30 mm×a height of 60 mm), and then filling it with an epoxy resin (product name: No815 produced by Japan Epoxy Resin Co., Ltd.) using triethylene triamine as a curing agent. Thereafter, the resultant resin was cut and polished by a cutting machine (product name: Labotom-3 manufactured by STRUERS) and a polishing machine (product name: EcoMet 6, VibroMet2 manufactured by BUEHLER) and observed through the electron microscope mentioned above.

The observation revealed that no plating was deposited on the surface of the second resin layer in any of Examples 1-4 and that the trenches was filled well with the metal layer.

These results proved that according to the method of Examples 1-4, no abnormal plating deposition should occur due to the adhesion of the catalyst onto the surface of the protective layer.

### INDUSTRIAL APPLICABILITY

As can be seen from the foregoing description, the present invention is suitable as a method for producing a printed wiring board by plating and as a printed wiring board produced by such a method.

### DESCRIPTION OF REFERENCE CHARACTERS

1 printed wiring board
2 first resin layer
3 conductor circuit
4 second resin layer
4a surface of second resin layer
5 via hole
6 trench
7 metal layer
8 protective layer
8a surface of protective layer
9 through hole
10 catalyst
11 plating film

1. A method for producing a printed wiring board, the method comprising at least the steps of:
forming a second resin layer over a first resin layer, on which a conductor circuit has been formed, so that the second resin layer covers the conductor circuit;
forming a water-repellent protective layer over the surface of the second resin layer;
cutting a through hole through the protective layer, and cutting a via hole and a trench in/through the second resin layer via the through hole;
applying a catalyst to the second resin layer to allow the catalyst to adhere to the via hole and the trench;
stripping the protective layer that has been formed over the surface of the second resin layer; and
filling the via hole and the trench, to each of which the catalyst has adhered, with a plating metal by electroless plating.

2. A method for producing a printed wiring board, the method comprising at least the steps of:
forming, over a first resin layer on which a conductor circuit has been formed, a second resin layer, of which the surface is covered with a water-repellent protective layer, so that the second resin layer covers the conductor circuit;
cutting a through hole through the protective layer, and cutting a via hole and a trench in/through the second resin layer via the through hole;
applying a catalyst to the second resin layer to allow the catalyst to adhere to the via hole and the trench;
stripping the protective layer that has been formed over the surface of the second resin layer; and
filling the via hole and the trench, to each of which the catalyst has adhered, with a plating metal by electroless plating.

3. The method of claim 1, wherein
in the step of stripping the protective layer, the protective layer is stripped with a stripping solution.

4. The method of claim 3, wherein
the stripping solution is an alkali metal aqueous solution or an alcohol solution.

5. The method of claim 4, wherein
the stripping solution has a concentration of 0.5 mol/l or less.

6. The method of claim 1, further comprising the steps of:
after the step of stripping the protective layer and before the step of filling with the plating metal, forming a plating film on respective surfaces of the via hole and the trench, to each of which the catalyst has adhered, by electroless plating; and stripping a residue of the protective layer on the surface of the second resin layer.

7. The method of claim 6, wherein
the step of stripping a residue of the protective layer on the surface of the second resin layer includes stripping the protective layer with a different stripping solution.

8. The method of claim 7, wherein
the different stripping solution is an alkali metal aqueous solution or an alcohol solution.

9. The method of claim 8, wherein
the different stripping solution has a concentrating of 0.4 mol/l or more 1.5 mol/l or less.

10. A printed wiring board produced by the method of claim 1.

11. The method of claim 2, wherein
in the step of stripping the protective layer, the protective layer is stripped with a stripping solution.

12. The method of claim 11, wherein
the stripping solution is an alkali metal aqueous solution or an alcohol solution.

13. The method of claim 12, wherein
the stripping solution has a concentration of 0.5 mol/l or less.

14. The method of claim 2, further comprising the steps of:
after the step of stripping the protective layer and before the step of filling with the plating metal, forming a plating film on respective surfaces of the via hole and the trench, to each of which the catalyst has adhered, by electroless plating; and stripping a residue of the protective layer on the surface of the second resin layer.

15. The method of claim 14, wherein
the step of stripping a residue of the protective layer on the surface of the second resin layer includes stripping the protective layer with a different stripping solution.

16. The method of claim 15, wherein
the different stripping solution is an alkali metal aqueous solution or an alcohol solution.

17. The method of claim 16, wherein
the different stripping solution has a concentrating of 0.4 mol/l or more 1.5 mol/l or less.

18. A printed wiring board produced by the method of claim 2.
